(19) United States
(12) Patent Application Publication
(10) Pub. No.: US 2013/0161775 A1
(43) Pub. Date: Jun. 27, 2013

(54) PHOTODETECTOR AND CORRESPONDING DETECTION MATRIX

(71) Applicants: Salim Boutami, Grenoble (FR); Laurent Frey, Fontaine (FR)

(72) Inventors: Salim Boutami, Grenoble (FR); Laurent Frey, Fontaine (FR)

(73) Assignee: COMMISSARIAT A L'ENERGIE ATOMIQUE ET AUX ENE ALT, Paris (FR)

(21) Appl. No.: 13/820,187

(22) PCT Filed: Sep. 9, 2011
(86) PCT No.: PCT/IB2011/053953

§ 371 Date: Mar. 1, 2013

(30) Foreign Application Priority Data
Sep. 9, 2010 (FR) 1003615

(51) Int. Cl. H01L 31/0248; H01L 31/0232

(52) U.S. Cl. CPC H01L 31/0248; H01L 31/0232
USPC 257/432

(57) ABSTRACT

The invention relates to a photodetector intended for the detection of incident light radiation in the visible and close infrared region, said photodetector comprising: a light-radiation-absorption structure (10) comprising a semiconductor material of index n1 and including a surface (13) exposed to the incident light radiation, and electrical connection means in contact with the aforementioned structure in order to convey a detection signal produced by the structure in response to the light radiation. The invention is characterised in that light-radiation-focusing means (12) are provided on the exposed surface (13), said means being formed by a single nanostructure having dimensions smaller than the wavelength of the light radiation in all directions of space.

The invention relates to the field of photodetectors, and in particular those whose light radiation absorption structure consists from a semiconductor material.

In general, an imager has a plurality of photodetectors, each of them having an antireflection layer.

In order to obtain a high-resolution imager, the size of the photodetectors is made small.

Thus, for a photodetector of substantially square cross section, the side length of this cross section may be of the order of the operating light radiation wavelength of the photodetector. The surface for exposure to the incident light radiation is therefore relatively small. It is apparent that in this case, because of diffraction, the antireflection layer provided on the exposure surface of the photodetector is no longer sufficiently effective in making the light radiation enter the photodetector.

Furthermore, when the size of the photodetector remains large, a significant part of the exposure surface of the photodetector may be covered with electrical connections, and therefore rendered opaque to light.

In certain cases, this opacified part may amount to 60% of the exposure surface of the photodetector. The usable region of the exposure surface is therefore relatively small.

Thus, only a fraction of the incident light radiation can enter the photodetector.

In both cases, the effectiveness of the photodetector is reduced.

It is an object of the invention to overcome these drawbacks by providing a photodetector intended for the detection of incident light radiation in the visible and near-infrared range, comprising:

a light radiation absorption structure comprising a semiconductor material having an index n₁ and having a surface for exposure to said incident light radiation and

electrical connection means in contact with said structure in order to convey a detection signal produced by this structure, in response to said light radiation,

characterized in that means for focusing said light radiation are provided on said exposure surface, said means consisting of a single nanostructure, made of a material having an index n₂, whose dimensions are less than the wavelength of the light radiation in all directions in space.

Thus, when only a small part of the exposure surface is not opaque, the invention makes it possible to focus the light radiation into the usable region of the photodetector, or to concentrate the light radiation below the nanostructure and in a region having small dimensions in relation to the exposure surface of the photodetector.

Furthermore, when the exposure surface is small owing to the size of the photodetector, these focusing means make it possible to reduce the fraction of the incident light radiation which does not reach it.

In both cases, the detection signal is stronger and the photodetector has higher performance.

With the photodetector according to the invention, it is no longer necessary to provide an antireflection layer.

Preferably, the nanostructure is made of a non-absorbent material.

Advantageously, the nanostructure is made of a material whose index n₂ is less than or equal to the index n₁ of the constituent material of the light radiation absorption structure and greater than that of the surrounding medium.

Preferably, the photodetector also comprises a lens arranged on the path of the incident light radiation, upstream of the focusing means.

The photodetector may also have a filter arranged on the path of the light radiation, upstream of the focusing means.

The invention also relates to a matrix for detection of incident light radiation, having a plurality of pixel structures, each pixel structure comprising a photodetector according to the invention.

Preferably, the detection matrix according to the invention also comprises reflecting means separating the pixel structures from one another and thus forming an optical barrier.

This configuration makes it possible to avoid a part of the light radiation scattered by the focusing means of a pixel structure being sent onto the neighboring pixel structures. This therefore makes it possible to avoid a loss of resolution of the image provided by an imager including this detection matrix.

These reflecting means may consist of a dielectric material whose index n₄ is less than the index n₁ of the constituent material of the light radiation absorption structure.

They may also be formed by the combination of a dielectric material and a metallic material.

In all cases, these reflecting means also make it possible to establish electrical isolation between the pixel structures.

Preferably, at least some of the pixel structures have focusing means of different dimensions, so as to be able to detect light radiation of different wavelengths.

Furthermore, a filter may be associated with each pixel structure.

The invention will be better understood and other objects, advantages and characteristics thereof will become clearer on reading the following description, which is given with reference to the appended drawings, in which:

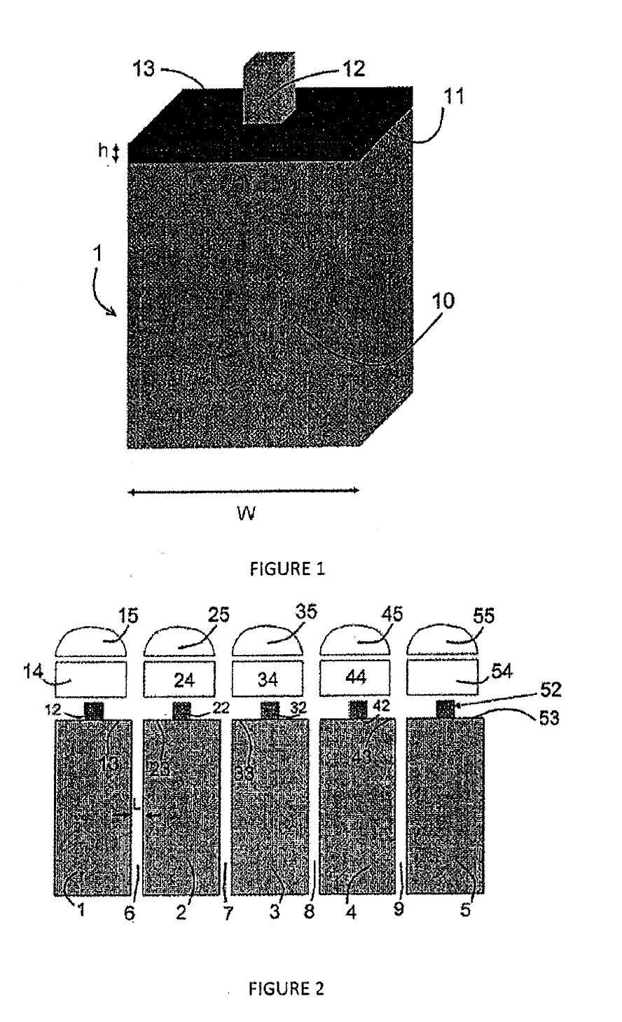

FIG. 1 is a perspective view of an exemplary embodiment of a photodetector according to the invention, and

FIG. 2 is a view in section of an exemplary embodiment of a detection matrix according to the invention.

The elements common to the two figures are denoted by the same references.

FIG. 1 illustrates a photodetector 1 according to the invention. It has a light radiation absorption structure 10 made of a semiconductor material.

The semiconductor materials are selected in order to cover a range of wavelengths lying in the visible and near-infrared, that is to say between about 400 and 900 nm. This wavelength range is the working range of the photodetector according to the invention.

Silicon, germanium, III-V compounds such as InP or GaAs, or InSb, or compounds such as CdHgTe may be mentioned in particular.

An intermediate layer 11, which may have the function of constituting an etch stop layer during production of the nanostructure, may be provided on this structure 10. Nevertheless, this layer 11 may be omitted.

It is a uniform layer, made of a material having an index n₃ which is intermediate between the index n₂ of the constituent material of the nanostructure and the index n₁ of the constituent material of the absorption structure. The index n₃ may be equal to n₁ or n₂.

This layer 11 may also constitute an antireflection layer. In this case, the index n₃ is intermediate between n₁ and n₂ and cannot be equal to n₁ or n₂.

Lastly, a nanostructure 12 is provided on this layer 11 or directly on the absorption structure 10.

This nanostructure 12 may be obtained by carrying out the following steps.

The first step consists in depositing a layer of a material having an index n₂ directly on the structure 10 or on the layer 11, when the latter is provided, this index being less than or equal to the index n₁ of the absorption structure 10.

The thickness of this layer of material having an index n₂ is of the order of the operating wavelength of the photodetector.

In order to produce this layer, various high-index materials may be used, that is to say materials whose index is greater than 1.75. In particular, Si, HfO₂, SiN, TiO₂ or ZnS may be mentioned.

The next step consists of a step of UV lithography, electron lithography or nanoimprint on resin and a step of dry etching, these two steps being carried out on the layer of material having an index n₂.

This etching step makes it possible to produce a nanostructure whose shape is selected by the designer of the photodetector and not imposed by the method by which it is obtained.

This second step makes it possible to produce the nanostructure.

This nanostructure is a single nanostructure, that is to say it has only one block per photodetector.

It is distinguished in particular by a periodic array of nanostructures. The latter furthermore has different optical behaviors, in particular promoting dispersion of the light rather than focusing thereof below the nanostructures.

Furthermore, the presence of a single nanostructure makes it possible to focus the light into a small region.

A final step may also be provided, namely a planarization step.

The photodetector 1 also has electrical connection means in contact with the structure 10, these not being illustrated in FIG. 1.

In general, the nanostructure therefore has the shape of a single block made of a single material. In all directions in space, the dimensions of this block are less than the detection wavelength, which lies between about 400 and 900 nm. Thus, the width and height of this block are less than 900 nm.

This condition makes it possible to ensure effective focusing of the light radiation below the nanostructure.

The nanostructure 12 illustrated in FIG. 1 substantially has the shape of a cube, although this does not imply limitation.

The nanostructure 12 may have other shapes, for example a parallelepiped with a rectangular base, or a cylinder with a circular or elliptical base.

However, in order to avoid any sensitivity to the polarization of the incident light radiation, nanostructures of cubic shape or of cylindrical shape with a circular base are preferred.

The fact that the shape of the nanostructure can be selected and adapted to the operating conditions is an advantage of the photodetector according to the invention.

This in particular distinguishes the photodetector according to the invention from devices of the prior art, for which the light focusing structure consists of a nanowire obtained by axial epitaxy. The shape of the nanostructure is then imposed.

Furthermore, the index n₂ of the material constituting the nanostructure is greater than the index of the surrounding medium, that is to say the medium lying above and around the nanostructure. This medium may typically be air or silica. This makes it possible for the nanostructure to focus the incident light radiation.

It is suitable for the materials used to produce the nanostructure not to be absorbent. This is because the light radiation is intended to be absorbed by the structure 10 lying below the nanostructure 12.

It is therefore desirable to avoid absorption of the light radiation in the nanostructure, so as to limit the losses.

In general, the nanostructure will preferably be produced in the central part of the surface 13 for exposure to the incident light radiation, or alternatively in a region of this exposure surface 13 in which no electrical connection means is provided.

It is to be noted that the structure and production of the photodetector are very simple because the nanostructure is made of a single material and can therefore be obtained easily from a layer of this material.

This also makes it possible to distinguish the photodetector according to the invention from systems known in the prior art.

Thus, the production of the nanostructure does not require the production of a pn junction because it is not designed to absorb the light radiation. This is not the case for devices comprising a nanowire fulfilling both a waveguide function and a photodiode function.

Likewise, the production of the nanostructure does not require very deep etchings because its dimensions are all less than the wavelength. This is not the case for devices which include a waveguide element produced by filling a narrow and deep opening formed in a dielectric layer. In fact, obtaining a deep opening is difficult because the etching often leads to a constriction toward the bottom of the opening. Furthermore, the filling of the opening can lead to the formation of bubbles or cavities which constitute traps for the light.

Furthermore, a reflective layer may be provided on the surface of the photodetector 1 on the opposite side from the exposure surface.

Reference is now made to FIG. 2, which illustrates a matrix for the detection of light radiation, in particular intended to be integrated into an imager.

This matrix has a plurality of pixel structures, a row of five structures being illustrated here.

Each pixel structure comprises a photodetector 1 to 5 corresponding to the one described with reference to FIG. 1. However, none of them has an intermediate layer, such as the layer 11.

All these photodetectors are produced on the same layer of semiconductor.

Each of these photodetectors 1 to 5 therefore has a nanostructure 12 to 52 on its surface 13 to 53 for exposure to the light radiation.

A filter 14 to 54 may be associated with each photodetector.

Furthermore, a microlens 15 to 55, which makes it possible to coarsely focus the incident light, may be provided upstream of the filter.

As shown in FIG. 2, the photodetectors 1 to 5 are separated by lateral trenches 6 to 9. These trenches may be filled with a suitable material, so as to constitute reflecting means, constituting both an optical and an electrical barrier. If no material is provided, it is air which will fulfill this double function.

By virtue of these trenches forming an optical barrier, it is possible to avoid part of the light scattered by the photodetector being transmitted to the neighboring photodetector. This configuration therefore makes it possible to gain on image resolution.

These trenches 6 to 9 are conventionally produced by dry etching, for example, after UV lithography or electron beam lithography.

Next, the trenches are filled with a dielectric material having an index n₄, the index n₄ being less than the index n₁ of the absorption structure so as to ensure electrical and optical isolation between the photodetectors. Preferably, the difference between the indices n₁ and n₄ is at least 0.25 in absolute value. The trenches may also be filled by the combination of a dielectric material and metal, this combination having at least one alternation of these materials.

Lastly, a planarization step may be carried out so that the material forming the optical barrier is present only in the trenches.

The following materials, which have a low index, may be used: SiO₂, MgF₂, Al₂O₃, SiOC, nanoporous SiOC or nanoporous silica.

By way of example, the silicon used to fill the trenches will have an index n₄ of 1.5, while the index n₁ of the absorption structure will be 3.5.

In the case in which the trenches are filled with a material having an index n₄ less than the index n₁, the thickness L of the trench must be sufficient so as to avoid light passing from one pixel structure to another by the tunnel effect.

That is why the thickness L will preferably satisfy the following relationship:

$$L > \frac{γ}{4 \cdot {n}_{4}}$$

where A is the wavelength of the incident light radiation.

This relationship is valid when the material filling the trenches is air or a dielectric material.

When the material is metal covered with a dielectric material or a dielectric material covered with metal, the thickness of the metal is greater than the skin depth, that is to say the thickness into which the light penetrates, so that the material is opaque to the light. This depends on the metal and the wavelength, but it is generally less than 100 nm. Furthermore, when the metal thus ensures optical isolation, the dielectric only needs to ensure electrical isolation. Its thickness is not then defined by the relationship above, but merely needs to be a few nanometers, in general at least 5 nm.

Various simulations have been carried out using finite element calculations, so as to demonstrate the advantages provided by the invention.

A first example relates to a photodetector according to the invention, the absorption structure of which has a substantially square cross section, with a side length of 1 μm and a height of 1.5 μm.

The constituent material of the absorption structure is silicon having an index n₁=3.5.

The photodetector has an exposure surface, the usable region of which represents only 30% of this surface. This photodetector corresponds, for example, to the situation in which electrical connection means partly mask the exposure surface.

The nanostructure of this photodetector is made of TiO₂, the index n₂ of which is 2.4.

The nanostructure has a height of 200 nm and its substantially square cross section has a side length of 200 nm. Furthermore, the surrounding medium is silica, having an index equal to 1.5.

The simulation carried out shows that, for a length of 650 nm, the percentage of the light radiation absorbed by the photodetector according to the invention is 29%.

By way of comparison, the simulation was carried out with a photodetector of a standard CMOS imager. This photodetector has an antireflection layer, and it is made of the same material and has the same dimensions as the photodetector according to the invention. However, this photodetector of course does not have the nanostructure making it possible to focus the light radiation.

The simulation shows that the percentage of the light radiation absorbed by this photodetector according to the prior art is 18%.

Thus, the gain in absorption is 11% in absolute value or 60% in relative value.

Another simulation was carried out with a photodetector whose absorption structure is made of silicon having an index n₁ of 3.5. Its height is 1.5 μm. Furthermore, the structure has a substantially square cross section with a side length of 500 nm, and the surrounding medium is silica.

In this example, the usable region consists of the entire surface for exposure to the light radiation.

With a conventional photodetector of the same composition and dimensions, having an antireflection layer, and for a wavelength of 650 nm, the percentage of the light radiation absorbed by the photodetector is 30%.

With a photodetector according to the invention, having a nanostructure made of TiO₂, with an index n₂ of 2.4, the percentage of the light radiation absorbed is 55%.

Thus, the gain in absorption of the light radiation is 25% in absolute value and 83% in relative value.

Lastly, another simulation was carried out with a matrix of photodetectors.

The latter have a height of 1.5 μm and a width of 500 nm, as in the previous example. They have the same structure as the photodetectors of the previous example.

In the case of the matrix according to the invention, the photodetectors are separated by reflecting means consisting of trenches of width L=100 nm, filled with silica having an index n₄=1.5. Thus, this index n₄ is less than n₁.

This matrix according to the invention is compared with a matrix having photodetectors which are identical but without a nanostructure and with an antireflection layer, these photodetectors also being separated by reflecting means. Thus, in both matrices, the trenches have the same dimensions and are filled with silica.

With the matrix according to the prior art, the level of absorption of the light radiation is 28%, while it is 41% with the matrix according to the invention.

The gain obtained is therefore 16% in absolute value and 64% in relative value.

These various simulations show that the nanostructure provided on the photodetectors according to the invention acts effectively as a means for focusing the light radiation.

As the percentage of the light radiation absorbed by the photodetector increases, its performance also increases.

It should also be noted that, when the photodetector according to the invention has an intermediate layer 11, its thickness may be limited when the photodetector is used in a detection matrix.

This is because, assuming that the trench present between the photodetectors is not formed in this intermediate layer, it is suitable for its height h to satisfy the following equation:

$$h < \frac{w}{4}$$

where w is the lateral dimension of the photodetector. This condition makes it possible to avoid a part of the light radiation passing from one photodetector to another.

In order to optimize the performance of the detection matrix according to the invention, the nanostructures 12 to 52 provided in the matrix may be of different sizes. Thus, each of them may be adapted to the length of the incident light radiation, after it has been filtered by the filters 14 to 54 before arriving on the matrix. It follows from these considerations that the invention is particularly suitable for very high-resolution imagers.

The reference signs inserted after the technical characteristics appearing in the claims are only intended to facilitate comprehension of the latter and do not limit the scope thereof.

1. A photodetector comprising:
a light radiation absorption structure comprising a semiconductor material, having an index, n₁, and a surface for exposure to incident light radiation, and
an electrical connection means in contact with the structure, which conveys a detection signal produced by the structure, in response to the light radiation,
wherein
a focusing means is on the surface,
the focusing means comprises a single nanostructure having a dimension less than a wavelength of the light radiation in all directions in space, and
the incident light radiation is in a visible range, a near-infrared range, or both.

2. The photodetector of claim 1, wherein the nanostructure comprises a non-absorbent material.

3. The photodetector of claim 1 , wherein the nanostructure comprises a material having an index, n₂,
wherein n₂ is less than or equal to the index n₁ and greater than an index of a surrounding medium.

4. The photodetector of claim 1, further comprising a lens arranged on a path of the incident light radiation, upstream of the focusing means.

5. The photodetector of claim 1, further comprising a filter arranged on a path of the incident light radiation, upstream of the focusing means.

6. A matrix for detection of incident light radiation, comprising a plurality of pixel structures, wherein each pixel structure comprises the photodetector of claim 1.

7. The matrix of claim 6, further comprising a reflecting means separating the pixel structures from one another and forming an optical barrier.

8. The matrix of claim 7, wherein the reflecting means comprises a dielectric material having an index, n₄, wherein n₄ is less than the index n₁.

9. The matrix of claim 7, wherein the reflecting means comprises a combination of a dielectric material and a metallic material.

10. The matrix of claim 6, wherein the pixel structures comprise a focusing means of a different dimension, in order to detect light radiation of a different wavelength.

11. The photodetector of claim 3, wherein the surrounding medium is air or silica.

12. The matrix of claim 8, wherein a difference between index n₁ and index n₄ is at least 0.25.

13. The photodetector of claim 1, further comprising an intermediate layer on the light radiation absorption structure,
wherein the intermediate layer has an index, n₃, between the index, n₂, and the index, n₁.

14. The photodetector of claim 13, wherein the index n₃ is equal to n₁, n₂, or both.

15. The photodetector of claim 13, wherein the intermediate layer comprises an antireflection layer, and n₃ is not equal to n₁ and n₂.

16. The photodetector of claim 3, wherein n₂ is greater than 1.75.

17. The photodetector of claim 3, wherein the material having an index n₂ is at least one selected from the group consisting of Si, HfO₂, SiN, TiO₂, and ZnS.

18. The photodetector of claim 1, wherein the nanostructure is cubic, parallelepiped with a rectangular base, cylindrical with a circular base, or cylindrical with an elliptical base.

19. The photodetector of claim 18, wherein the nanostructure is cubic or cylindrical with a circular base.

20. The matrix of claim 9, wherein a thickness of the metallic material is less than 100 nm and a thickness of the dielectric material is at least 5 nm.
